(19) United States
(12) Patent Application Publication
(10) Pub. No.: US 2014/0362649 A1
(43) Pub. Date: Dec. 11, 2014

(54) SEMICONDUCTOR MEMORY DEVICE

(71) Applicant: Chih-Cheng Hsiao, Taichung City (TW)

(72) Inventor: Chih-Cheng Hsiao, Taichung City (TW)

(21) Appl. No.: 14/300,736

(22) Filed: Jun. 10, 2014

(30) Foreign Application Priority Data
Jun. 11, 2013 (TW) 102120736

(51) Int. Cl. G11C 7/12; G11C 7/02

(52) U.S. Cl. CPC G11C 7/12; G11C 7/02
USPC 365/189.05

(57) ABSTRACT

A semiconductor memory device includes a plurality of memory cell groups, a data line unit, a buffer unit and a bias voltage unit. The data line unit is coupled to the memory cell groups for transmitting to-be-read data and to-be-written data. The buffer unit includes a plurality of tri-state buffers coupled to the data unit. The bias voltage unit is coupled to the data unit to supply a preset bias voltage thereto. The tri-state buffers segment the data line unit into smaller units, thereby reducing parasitic capacitance of the data line unit, and consequently the power consumption of the semiconductor memory device.

### CROSS-REFERENCE TO RELATED APPLICATION

This application claims priority of Taiwanese Application No. 102120736, filed on Jun. 11, 2013.

### BACKGROUND OF THE INVENTION

1. Field of the Invention

The invention relates to a memory device, more particularly to a semiconductor memory device.

2. Description of the Related Art

FIG. 1 illustrates a conventional semiconductor memory device. The semiconductor memory device includes a memory cell group, a plurality of parallel data lines 11 connected to the memory cell group, a plurality of parallel control lines 12 connected to the memory cell group, and a plurality of sense amplifiers 14 coupled respectively to the data lines 11.

The memory cell group includes a plurality of memory cells 13 arranged in the form of an array. The control lines 12 intersect the data lines 11, and are electrically isolated from the data lines 11. The control lines 12 are for transmitting a control signal to the memory cells 13, in order to control the memory cells 13 to output the data stored therein as a data signal.

However, as the demand for capacity of the memory device increases, a memory cell group 10 with a greater number of memory cells 13 may be preferable. The data lines 11 that are coupled to the memory cells 13 are consequently made longer, which inevitably increases their parasitic capacitance.

Because of the parasitic capacitance of the data lines 11, a voltage that is outputted by the memory cells 13 may not be efficiently propagated to the data lines 11. As a result, the sense amplifiers 14 are employed to assist in amplifying the voltage on the data lines 11, in order to facilitate data transmission.

Nonetheless, the sense amplifiers 14 may be an undesired addition to the conventional semiconductor memory device due to their relatively large power consumption. Therefore, it may be beneficial to address the issue of the parasitic capacitance of the data lines, and to omit the sense amplifiers 14 altogether.

### SUMMARY OF THE INVENTION

Therefore, the object of the present invention is to provide a semiconductor memory device that may alleviate at least one of the above drawbacks of the prior art, and that does not require a sense amplifier.

According to one aspect, a semiconductor memory device of the present invention comprises a memory cell array, a data line unit, a control unit, a buffer unit, and a bias voltage unit.

The memory cell array includes a plurality of memory cell groups. Each of the memory cell groups includes a plurality of memory cells. Each of the memory cells has a read terminal and a write terminal.

The data line unit is coupled to the memory cell groups, and includes a plurality of read bit lines and a plurality of write bit lines that are spaced apart and electrically isolated from each other.

Each of the read bit lines is coupled to the read terminals of the memory cells of a respective one of the memory cell groups for transmitting to-be-read data. Each of the write bit lines is coupled to the write terminals of the memory cells of a respective one of the memory cell groups for transmitting to-be-written data.

The control unit is coupled to the memory cell groups, and is electrically isolated from the data line unit. The control unit includes a plurality of read word lines and a plurality of write word lines that are spaced apart and electrically isolated from each other.

The read word lines are configured to transmit a read control signal to the memory cell groups. The write word lines are configured to transmit a write control signal to the memory cell groups.

The buffer unit includes a plurality of tri-state buffer sets. Each of the tri-state buffer sets includes a string of tri-state buffers that are coupled in series with a respective one of the read bit lines.

Each of the tri-state buffers has an input terminal coupled to the read terminal of a respective one of the memory cells to receive the to-be-read data, and an output terminal coupled to the input terminal of a succeeding one of the tri-state buffers in the string. The tri-state buffers are controlled to switch between a conducting state and a non-conducting state.

The bias voltage unit is coupled to the read bit lines and is operable to supply a preset bias voltage to the read bit lines.

According to another aspect, a semiconductor memory device of to the present invention comprises a memory cell array, a data line unit, a control unit, a buffer unit, and a bias voltage unit.

The memory cell array includes a plurality of memory cell groups. Each of the memory cell groups includes a plurality of memory cells, and each of the memory cells includes a data terminal.

The data line unit includes a plurality of data lines spaced apart and electrically isolated from each other. Each of the data lines is coupled to the data terminals of the memory cells of a respective one of the memory cell groups.

The control unit is coupled to the memory cell groups, and includes a plurality of control lines that are spaced apart and electrically isolated from each other for transmitting a control signal to the memory cell groups.

The buffer unit includes a plurality of tri-state buffer sets. Each of the tri-state buffer sets includes a string of tri-state buffers that are coupled in series with a respective one of the data lines.

Each of the tri-state buffers has an input terminal coupled to the data terminal of a respective one of the memory cells to receive data therefrom, and an output terminal coupled to the input terminal of a succeeding one of the tri-state buffers in the string. The tri-state buffers are controlled to switch between a conducting state and a non-conducting state.

The bias voltage unit is coupled to the data lines and is operable to supply a preset bias voltage to the data lines.

According to yet another aspect, a semiconductor memory device of the present invention comprises a memory cell array, a data line unit, a control unit, a buffer unit, and a bias voltage unit.

The memory cell array includes a plurality of memory cell groups. Each of the memory cell groups includes a plurality of memory cells.

The data line unit is coupled to the memory cell groups, and includes a plurality of data lines spaced apart and electrically isolated from each other.

The control unit is coupled to the memory cell groups, and includes a plurality of control lines spaced apart and electrically isolated from each other for transmitting a control signal to the memory cell groups.

The buffer unit includes a plurality of tri-state buffer sets. Each of the tri-state buffer sets includes a string of tri-state buffers that are disposed on a signal transmission path of a respective one of the data lines.

Each of the tri-state buffers has an input terminal coupled to a respective one of the memory cells to receive data therefrom, and an output terminal coupled to the input terminal of a succeeding one of the tri-state buffers in the string. The tri-state buffers are controlled to switch between a conducting state and a non-conducting state.

The bias voltage unit is coupled to the data lines, and is operable to supply a preset bias voltage to the data lines.

### BRIEF DESCRIPTION OF THE DRAWINGS

Other features and advantages of the present invention will become apparent in the following detailed description of the preferred embodiments with reference to the accompanying drawings, of which:

FIG. 1 is a schematic block diagram of a conventional semiconductor memory device;

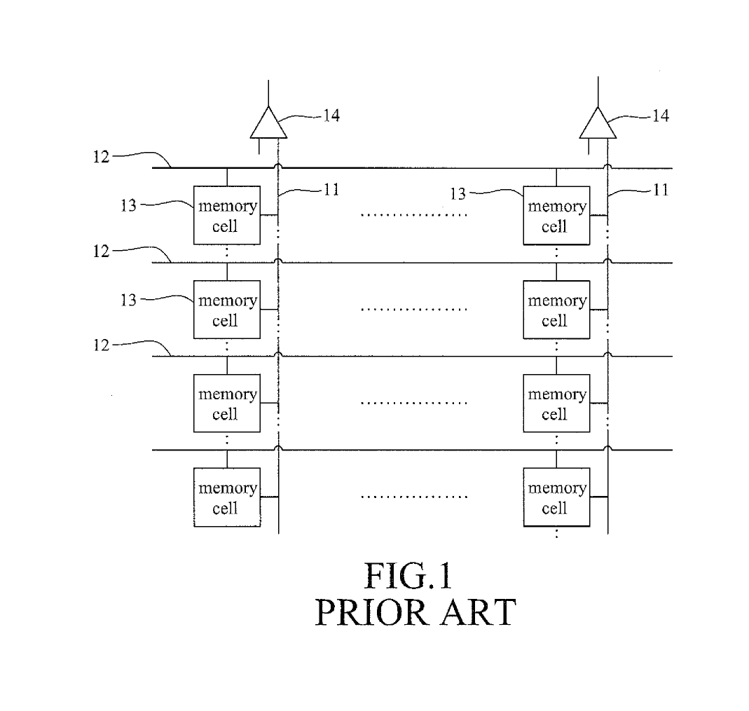

FIG. 2 is a schematic block diagram of the first preferred embodiment of a semiconductor memory device according to the invention;

FIG. 3 is a schematic circuit diagram of a memory cell of the semiconductor memory device according to the first preferred embodiment;

FIG. 4 is a schematic circuit diagram of an alternative implementation of a tri-state buffer used in the first preferred embodiment;

FIG. 5 is a schematic block diagram of a variation of the first preferred embodiment;

FIG. 6 is a schematic block diagram of the second preferred embodiment of a semiconductor memory device according to the invention;

FIG. 7 is a schematic circuit diagram of a variation of the second preferred embodiment; and

FIG. 8 is a schematic block diagram of the third preferred embodiment of a semiconductor memory device according to the invention.

### DETAILED DESCRIPTION OF THE PREFERRED EMBODIMENTS

Before the present invention is described in greater detail, it should be noted that like elements are denoted by the same reference numerals throughout the disclosure.

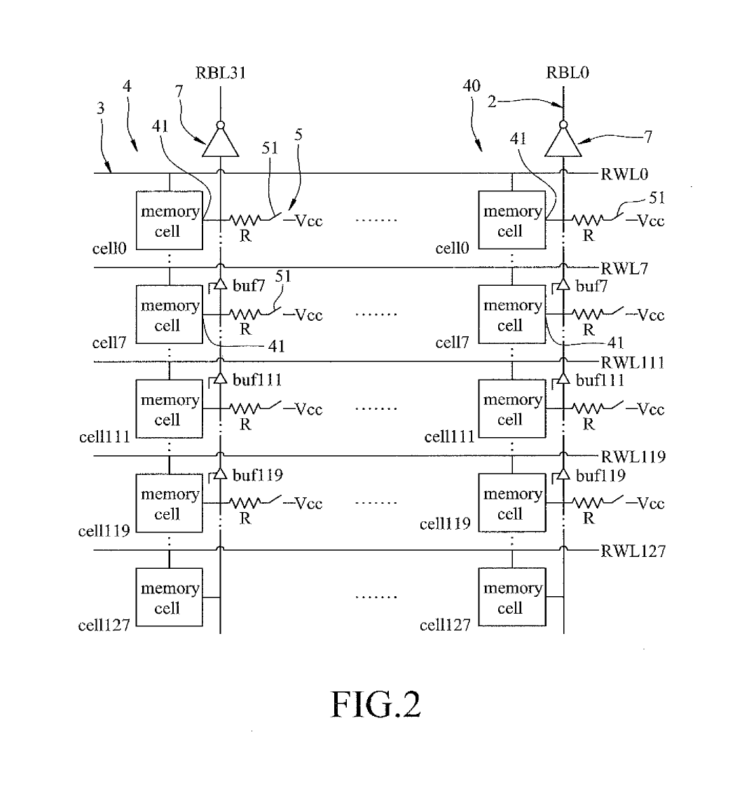

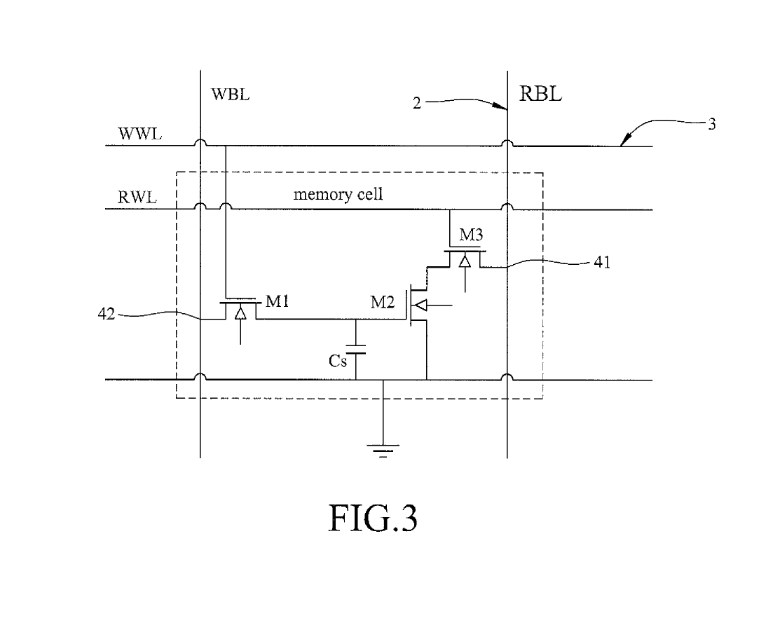

As shown in FIG. 2, the first preferred embodiment of a semiconductor memory device according to the present invention comprises a data line unit 2, a control line unit 3 (see FIG. 3), a memory cell array 4, a buffer unit, a bias voltage unit 5, and an inverting unit.

The semiconductor memory device in the embodiments of this invention may be coupled to a processor such as a central processing unit (not depicted in the drawings), and can be accessed by the processor via a controller (not depicted in the drawings) to serve as, for example, a cache.

In this embodiment, a memory cell array 4 that includes 32 memory cell groups 40 is presented. Each of the memory cell groups 40 may include a plurality of memory cells (cell). For example, 128 memory cells (labeled as (cell0), (cell7), . . . , (cell127), etc.) are incorporated in each of the memory cell groups 40 shown in FIG. 2, resulting in a 128*32 bit memory cell array 4. Each of the memory cells (cell) has a read terminal 41 and a write terminal 42 (see FIG. 3).

The data line unit 2 is coupled to the controller and the memory cell array 4, and includes a plurality of read bit lines (RBL) and a plurality of write bit lines (WBL) that are spaced apart and electrically isolated from each other, as best shown in FIG. 3. The write bit lines (WBL) are omitted in FIG. 2 for the sake of clarity. The read bit lines (RBL) are configured to transmit to-be-read data that is stored in the memory cells (cell), and the write bit lines (WBL) are configured to transmit to-be-written data (from, for example, the controller) to the memory cells (cell).

Referring to FIG. 3, the control line unit 3 is coupled to the controller and the memory cell groups 40, and includes a plurality of read word lines (RWL) and a plurality of write word lines (WWL) that are spaced apart and electrically isolated from each other. The control line unit 3 is configured to transmit control signals including a read control signal and a write control signal, in order to configure the states of the memory cell groups 40.

In particular, the read word lines (RWL) are configured to transmit the read control signal to the memory cell groups 40 for controlling the memory cells (cell) thereof to be readable/non-readable. The write word lines (WWL) are configured to transmit the write control signal to the memory cell groups 40 for controlling the memory cells (cell) thereof to be writeable/non-writeable.

Referring back to FIG. 2, the buffer unit includes a plurality of tri-state buffer sets. Each of the tri-state buffer sets includes a string of tri-state buffers (buf) (e.g., buf7, buf111, . . . , buf119, etc.) that are coupled in series with a respective one of the read bit lines (RBL).

On each of the read bit lines (RBL), a plurality of memory cells (cell) are coupled to common nodes of adjacent pairs of the tri-state buffers (buf) through the read terminals 41 thereof. For example, in this embodiment, eight memory cells (cell) are coupled to the common node of every adjacent pair of the tri-state buffers (buf).

Each of the tri-state buffers (buf) has an input terminal, an output terminal, and a control terminal. The input terminal is coupled to the read terminal 41 of a respective one of the memory cells (cell) to receive the to-be-read data. The output terminal is coupled to the input terminal of a succeeding one of the tri-state buffers in the string (Except for a first one of the tri-state buffers (buf7) in each of the strings, whose output terminal is coupled to the inverting unit 7).

The control terminal is to be coupled to a system control unit (not depicted in the drawings), and is operable to receive a command signal from the system control unit, such that the tri-state buffer (buf) is operable to switch between a conducting state and a non-conducting state.

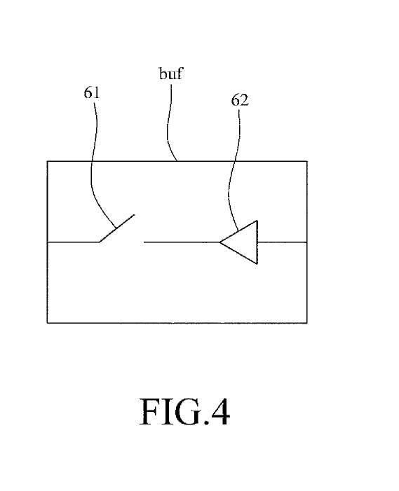

It is worth noting that, in some embodiments, the tri-state buffers (buf) may be embodied using other configurations that can be switched between a conducting state and a non-conducting state. For example, FIG. 4 illustrates one such configuration that includes a combination of a switch component 61 and a buffer component 62 connected in series.

In some embodiments, the memory cells (cell) may be embodied using dynamic random access memory (DRAM). In this embodiment, each of the memory cells (cell) is a three-transistor dynamic random access memory (3T-DRAM) cell which is a volatile memory cell that employs n-type metal-oxide-semiconductor field-effect transistors (N-MOS transistors). However, various types of memory cells may be employed in other embodiments.

FIG. 3 illustrates one such memory cell (cell) used in this embodiment. The memory cell (cell) includes a first transistor (M₁), a second transistor (M₂), a third transistor (M₃), and a capacitor (Cs).

The first transistor (M₁) has a first terminal, a second terminal coupled to the write bit line (WBL) to serve as the write terminal 42, and a control terminal coupled to the write word line (WWL).

The second transistor (M₂) has a first terminal, a second terminal disposed to receive a reference voltage, and a control terminal coupled to the first terminal of the first transistor (M₁). In this embodiment where N-MOS transistors are used, the reference voltage is a ground voltage.

The capacitor (Cs) has one end coupled to the control terminal of the second transistor (M₂), and another end disposed to receive the reference voltage.

The third transistor (M₃) has a first terminal coupled to the input terminal of the tri-state buffer to serve as the read terminal 41, a second terminal coupled to the first terminal of the second transistor (M₂), and a control terminal coupled to the read word line (RWL).

In operation, the first transistor (M₁) is controlled by the write control signal transmitted from the write word line (WWL) to switch between conducting and non-conducting states. That is, when the memory cell (cell) is selected to have data written therein, the write word line (WWL) is set to a high voltage level (e.g., at an operating voltage), thereby switching the first transistor (M₁) to the conducting state.

The second transistor (M₂) is controlled by the electrical energy stored in the capacitor (Cs) to switch between conducting and non-conducting states. That is, when the capacitor (Cs) is sufficiently charged to provide a voltage higher than the threshold voltage of the second transistor (M₂), the second transistor (M₂) will be switched to the conducting state.

The third transistor (M₃) is controlled by the read control signal from the read word line (RWL) to switch between conducting and non-conducting states. That is, when one of the memory cells (cell) is selected so as to read the data stored therein, the corresponding read word line (RWL) is set to a high voltage level (e.g., at the operating voltage), thereby switching the third transistor (M₃) to the conducting state.

It is noted that, in other embodiments, various numbers of memory cell groups 40 and/or various size of each of the memory cell groups 40 may be employed to constitute a larger semiconductor memory device.

Referring back to FIG. 2, the bias voltage unit 5 is operable to control supply of a preset bias voltage (Vcc) to the read bit lines (RBL). In this embodiment where N-MOS transistors are used, the preset bias voltage (Vcc) is the operating voltage. The preset bias voltage (Vcc) may be supplied by, for example, a voltage source (not depicted in the drawings).

In this embodiment, the bias voltage unit 5 is operable, with respect to each of the read bit lines (RBL), to switch between a biasing mode and a non-biasing mode. In the biasing mode, the preset bias voltage (Vcc) is supplied to each of the read bit lines (RBL). In the non-biasing mode, the preset bias voltage (Vcc) is not supplied to each of the read bit lines (RBL). By default, the bias voltage unit 5 is kept in the biasing mode. When data is to be read from the memory cell groups 40, the bias voltage unit 5 is switched to the non-biasing mode.

In this embodiment, the bias voltage unit 5 includes a plurality of resistors (R) and a plurality of switches 51. Each of the resistors (R) has one end coupled to one of the read bit lines (RBL). On each of the read bit lines (RBL), at least one resistor (R) is coupled to a common node of every adjacent pair of the tri-state buffers (buf).

Each of the switches 51 couples another end of a respective one of the resistors (R) to the voltage source that supplies the preset bias voltage (Vcc). The switches 51 are closed when the bias voltage unit 5 is operated in the biasing mode, thus allowing the preset bias voltage (Vcc) to be supplied to the read bit lines (RBL). Conversely, the switches 51 are opened when the bias voltage unit 5 is operated in the non-biasing mode.

The resistors (R) may be embodied as poly resistor, transistor resistor, etc. In embodiments where the voltage source has desired resistive characteristics and/or includes components equivalent to a resistor, the resistors (R) may be omitted.

According to the configuration set forth in this embodiment (i.e., N-MOS transistors are used), the preset bias voltage (Vcc) is set to a high voltage level (e.g., at the operating voltage). Alternatively, when P-MOS transistors are used, the preset bias voltage (Vcc) may be set to a low voltage level (e.g., at the ground voltage).

The inverting unit includes a plurality of inverters 7 each disposed at an end of a respective one of the read bit lines (RBL) for obtaining an inverted voltage level of the to-be-read data that is to be fed to the controller.

In operation, each of the memory cells (cell) can be controlled by the control signals to operate in one of a write mode and a read mode. Generation of the control signals may be done by the controller that is coupled to the semiconductor memory device.

For example, when data is to be written into a selected one of the memory cells (cell) (i.e., the memory cell (cell) is to be switched to the write mode), the write control signal sets a corresponding one of the write word lines (WWL) to a high voltage level (e.g., the operating voltage) for switching the first transistor (M₁) to the conducting state. Afterwards, a corresponding one of the write bit lines (WBL) is able to transmit the to-be-written data to the first transistor (M₁) for subsequent storage in the capacitor (Cs).

Alternatively, when data is to be read from the selected one of the memory cells (cell) (i.e., the memory cell (cell) is to be switched to the read mode), the bias voltage unit 5 is switched to the non-biasing mode. This is to ensure that the input terminals of the tri-state buffers (buf) on a corresponding one of the read bit line (RBL) are adjusted to the preset bias voltage. Afterward, the read control signal sets the read word line (RWL) to a high voltage level, in order to fetch the voltage level associated with the capacitor (Cs) of the selected one of the memory cells (cell).

Moreover, on the corresponding one of the read bit line (RBL), the tri-state buffers (buf) that are disposed between the read terminal 41 of the selected one of the memory cells (cell) and the inverting unit is controlled to be in the conducting state, while other tri-state buffers (buf) are controlled to be in the non-conducting state. This is done because, when a tri-state buffer (buf) is in the conducting state, data read from the coupled memory cell (cell) will be relayed to the read bit line (BBL). As a result, when multiple tri-state buffers (buf) are left conducting, there may be occurrence of undesired effects, such as errors due to non-selected data being read, and additional power dissipation. Therefore, it is necessary to minimize the number of tri-state buffers (buf) that are operated in the conducting state.

For example, when one memory cell (cell) belonging to the memory cell group 40 that is coupled to the tri-state buffer (buf111) is selected, the third transistor (M₃) of the selected memory cell (cell) outputs the to-be-read data to the tri-state buffer (buf111). Subsequently, the tri-state buffer (buf119) is switched to the non-conducting state, and other tri-state buffers (buf) remain in the conducting state. The result is that the voltage of the capacitor (Cs) being outputted to the read bit line (RBL), and then inverted by the inverter 7 before being transmitted to the controller.

Details of the read operation are described as follows with reference to FIGS. 2 and 3. For the selected one of the memory cells (cell), when the capacitor (Cs) is discharged (i.e., the data stored in the memory cell (cell) is ‘0’), the second transistor (M₂) is in the non-conducting state, and the first terminal of the third transistor (M₃) (i.e., the read terminal 41 of the memory cell (cell)) is in a high-impedance state. As a result, the voltage being fed to the read bit line (RBL) as the to-be-read data will be the voltage at the input terminal of the tri-state buffer (buf111) which has been adjusted to the preset bias voltage (high voltage level) by the bias voltage unit 5. After being inverted by the inverter 7, the voltage that correctly reflects the voltage of the capacitor (Cs) is outputted to the controller.

On the other hand, when the capacitor (Cs) is charged (i.e., the data stored in the memory cell (cell) is ‘1’), the second transistor (M₂) is in the conducting state, and the first terminal of the second transistor (M₂) is at the reference voltage (i.e., the ground voltage). The reference voltage is then fed to the corresponding read bit line (RBL). Similarly, after being inverted by the inverter 7, the voltage that correctly reflects the voltage of the capacitor (Cs) is outputted to the controller.

In the above configuration, the bias voltage unit 5 is switched to the non-biasing mode when data is to be read from the memory cell groups 40. For example, in the embodiment as shown in FIG. 2, the switch components 61 are opened in such occasions, thereby cutting off the electrical connection between the read bit line (RBL) and the preset bias voltage (Vcc).

As a result, when the to-be-read data is an inverted form of the preset bias voltage (Vcc), the undesired situation that electrical current flowing across the resistors (R) due to the large voltage across the resistors (R) may be prevented, reducing unnecessary power dissipation attributed thereto.

The switching-off of the bias voltage unit 5 may be implemented in a number of ways. For example, right after the read bit lines (RBL) are biased to the preset bias voltage (Vcc), the bias voltage unit 5 may be switched to the non-biasing mode. Alternatively, when a charge period the bias voltage unit 5 takes to bias the read bit lines (RBL) to the preset bias voltage (Vcc) is known (by, for example, estimating the parasitic capacitance and resistance of the read bit lines (RBL)), the bias voltage unit 5 may be switched to the biasing mode in the beginning of a read period of an operation cycle, and then switched to the non-biasing mode after a bias period, that corresponds to the charge period, has elapsed. In some examples, the bias period may be set at a tenth of the read period.

In brief, some of the advantages of this embodiment may be summarized as follows.

It is known that, in conventional semiconductor memory devices, when a larger number of memory cells (cell) are incorporated in a memory cell group 40, the read bit lines (RBL) must be made longer, and the parasitic capacitance and an effective resistance on each of the read bit lines (RBL) becomes relatively large and may adversely affect signal transmission efficiency on each of the read bit lines (RBL). For example, when a high voltage is to be transmitted via the read bit lines (RBL), the large parasitic capacitance and the effective resistance of the read bit lines (RBL) may prevent the voltage from being pulled up to the correct high voltage.

In this embodiment, each of the read bit lines (RBL) may be considered “segmented” by 8 tri-state buffers (buf) into 16 shorter units. In this case, the parasitic capacitance attributed to the memory cells (cell) can be reduced to 1/16 compared to the conventional configuration. With a substantially smaller parasitic capacitance and driving capability provided by the tri-state buffers (buf), the read bit lines (RBL) can be biased to the desired voltages more efficiently, and do not require additional sense amplifiers to ensure proper operation, thereby reducing the power consumption dramatically.

Moreover, the inclusion of the tri-state buffers (buf) allows the semiconductor memory device to operate in a higher clock frequency. For example, a semiconductor memory device that does not include the tri-state buffers (buf) may have a maximum operating frequency of 20 MHz, under which the semiconductor memory device functions normally. When the tri-state buffers (buf) are taken into consideration, the maximum operating frequency of the semiconductor memory device can be increased to 320 MHz.

The bias voltage unit 5 is operable to switch between the biasing mode and the non-biasing mode. When in the biasing mode, the input terminals of the tri-state buffers (buf) and the read bit lines (RBL) are provided with the preset bias voltage (Vcc), thereby preventing the input terminals from being in a floating state, which may induce large power consumption of the tri-state buffers (buf). Furthermore, by opening the switch components 61 when data is to be read from the memory cells (cell), unnecessary power dissipation that is attributed to electrical current flowing through the resistors (R) can be reduced.

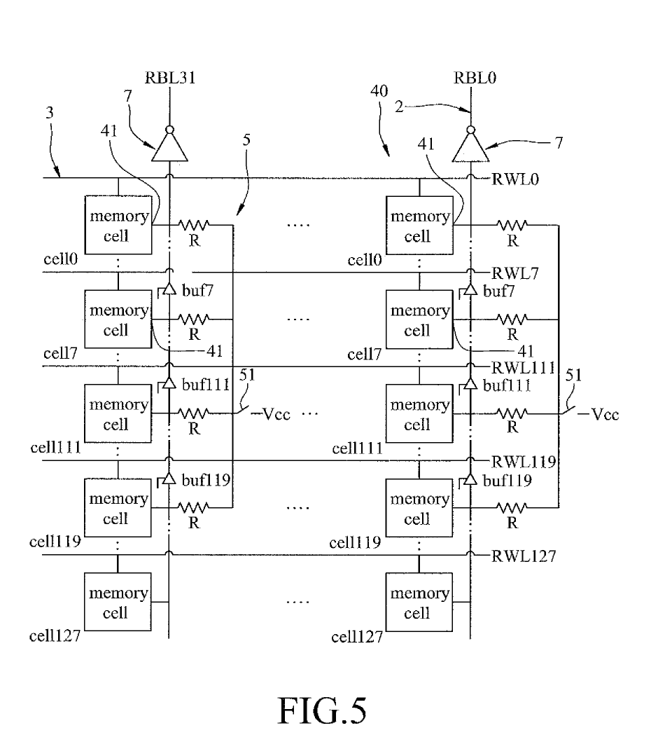

FIG. 5 illustrates a variation of the first preferred embodiment. In this variation, for each of the memory cell groups 40, the bias voltage unit 5 includes a single switch 51 and a plurality of resistors (R) each having an end coupled to the read bit line (RBL) and another end coupled to the switch 51, which is coupled to the preset bias voltage (Vcc). One advantage of this variation is that the number of switches 51 used for the entire semiconductor memory device is much less compared to that in the embodiment shown in FIG. 2, thereby reducing the overall size and cost of the semiconductor memory device. It is known that in some variations, other number of the switches 51 may be employed. For example, the bias voltage unit 5 may include only a single switch 51 coupling between the resistors (R) and the preset bias voltage (Vcc).

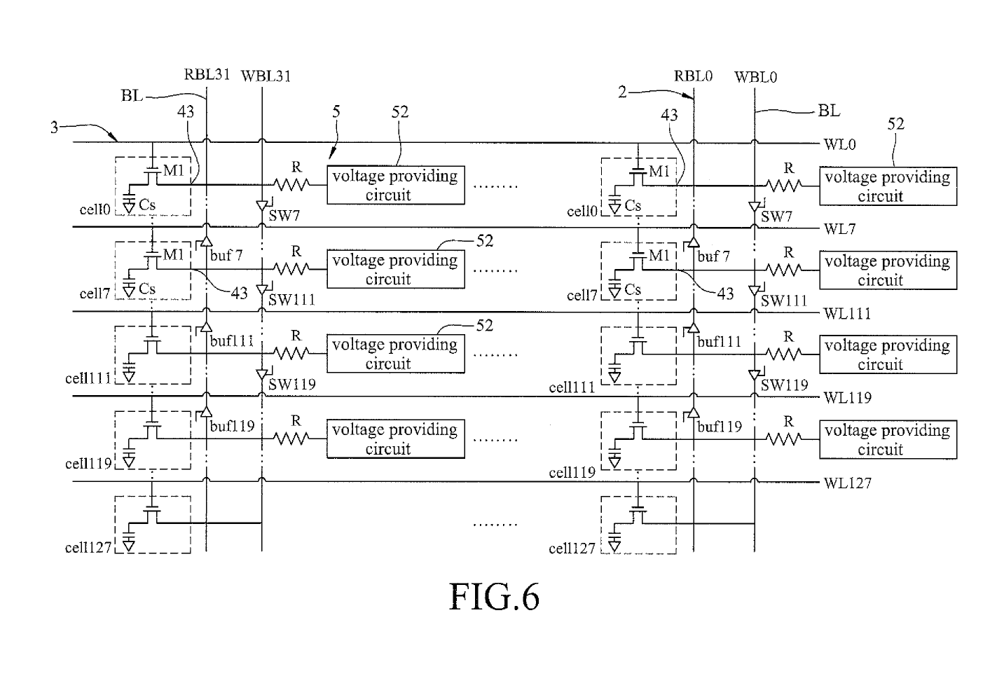

As shown in FIG. 6, the second preferred embodiment of the semiconductor memory device according to the present invention has a structure similar to that of the first preferred embodiment. The main differences between this embodiment and the first preferred embodiment reside in the following.

The memory cells (cell) in this embodiment are embodied as one-transistor dynamic random access memories (1T-DRAM) each including a transistor and a capacitor.

The transistor of each of the memory cells (cell) of this embodiment includes a control terminal, a first terminal coupled to the capacitor, and a second terminal. It is known that for the 1T-DRAMs, the second terminal is used for reading data therefrom and writing data thereto. As a result, the write bit line (WBL) and the read bit line (RBL) are both coupled to the second terminal serving as a data terminal 43.

In this case, the data read from the memory cells (cell) have an identical phase as that transmitted to the read bit lines (RBL). Therefore, the semiconductor memory device of this embodiment does not require the inverters 7 of the semiconductor memory device of the first preferred embodiment.

In this embodiment, the semiconductor memory device includes a first data line unit that includes a plurality of first data lines spaced apart and electrically isolated from each other. Each of the first data lines is coupled to the data terminals 43 of the memory cells (cell) of a respective one of the memory cell groups 40. Particularly, the first data lines are read bit lines (RBL) for transmitting the to-be-read data.

The semiconductor memory device further includes a second data line unit and a write controlling component unit. The second data line unit includes a plurality of second data lines that are spaced apart and electrically isolated from each other. Each of the second data lines is a write bit line (WBL) coupled to the data terminals 43 of the memory cells (cell) of a respective one of the memory cell groups 40 for transmitting the to-be-written data. In other words, while each of the first data lines is spaced apart and electrically isolated from other first data lines and each of the second data lines is spaced apart and electrically isolated from other second data lines, each of the first data lines is coupled to a respective one of the second data lines.

The write controlling component unit includes a plurality of write controlling component sets. Each of the plurality of write controlling component sets includes a string of write controlling switches (e.g., SW7, SW111, etc.) that are coupled in series with a respective one of the write bit lines (WBL). Each of the write controlling switches (SW) has an input terminal coupled to the data terminal 43 of a respective one of the memory cells (cell), and an output terminal coupled to the input terminal of a succeeding one of the write controlling switches (SW) in the string. The write controlling switches (SW) are controlled to switch between a conducting state and a non-conducting state.

The reason for inclusion of the write controlling component unit (SW) is that the memory cells (cell) used in this embodiment are implemented using 1T-DRAM which employs a common terminal for both reading and writing data. As a result, both read bit lines (RBL) and the write bit lines (WBL) are coupled to the data terminals 43 of the memory cells (cell). In order to prevent the voltage levels of the read bit lines (RBL) and the write bit lines (WBL) from interfering with each other, the write controlling component unit must be incorporated. Furthermore, the write controlling component unit can similarly serve to “fragment” the write bit lines (WBL) into smaller units. As a result, the parasitic capacitance attributed to the write bit lines (WBL) can be greatly reduced compared to the conventional configuration.

The bias voltage unit 5 includes a plurality of voltage providing circuit 52 and a plurality of resistors (R). Each of the resistors (R) is coupled between a respective one of the voltage providing circuits 52 and one of the write bit lines (WBL) (i.e., and a corresponding one of the read bit lines (RBL)). In this embodiment, at least one resistor (R) and at least one voltage providing circuit 52 is coupled to a common node of every adjacent pair of the tri-state buffers and a common node of every adjacent pair of the write controlling switches (SW) for supplying the preset bias voltage to the data lines when the bias voltage unit 5 is operated in the biasing mode. It is noted that, in embodiments where the voltage source itself has an equivalent resistance (e.g., being other than a ground), the resistors (R) may be omitted.

In operation, when data is to be written into one of the memory cells (cell), the to-be-written data is transmitted from the controller to the corresponding write bit line (WBL). Also, the corresponding write word line (WWL) transmits the write control signal to the one of the memory cells (cell) to enable write operation.

Subsequently, parts of the write bit line (WBL) between the one of the memory cells (cell) and the controller must be configured to establish a closed circuit in order for the data to reach the one of the memory cells (cell). For example, when it is intended to write data into the particular memory cell (cell7), the write controlling switch (SW7) must be closed, while all other write controlling switches (SW) are opened. Additionally, all the tri-state buffers (buf) on the corresponding read bit line (RBL) must be opened. Such a configuration prevents undesired interference between the read bit line (RBL) and the write bit line (WBL) from happening.

Alternatively, when data is to be read from one of the memory cells (cell), the bias voltage unit 5 first provides the preset bias voltage to the corresponding read bit line (RBL) before switching to the non-biasing mode. Also, the corresponding read word line (RWL) transmits the read control signal to the one of the memory cells (cell) to enable read operation.

Subsequently, parts of the read bit line (RBL) between the one of the memory cells (cell) and the controller must be configured to establish a closed circuit in order for the data to reach the controller. For example, when it is intended to read data from the particular memory cell (cell7), the tri-state buffer (buf7) must be closed, while all other tri-state buffers (buf) are opened. Additionally, all the write controlling switches (SW) on the corresponding write bit line (WBL) must be opened to cut off possible current flow. Such a configuration prevents undesired interference between the read bit line (RBL) and the write bit line (WBL) from happening.

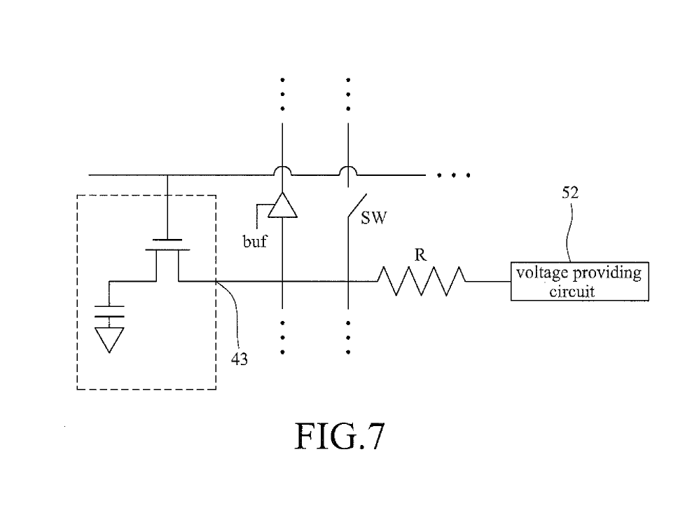

Depending on requirements, the write controlling switches (SW) may be embodied as normal switch components (as shown in FIG. 7) or tri-state buffers (buf) that have driving capability. In some embodiments, a driving circuit (not depicted in the drawings) may be incorporated at one end of each of the write bit lines (WBL) in order to decrease the time for driving the voltage thereon.

In brief, when 1T-DRAMs are used as the memory cells (cell), the data terminals 43 are responsible for both read and write operations. Therefore, the parasitic capacitance on the write bit line (WBL) may adversely affect the capability of the memory cells (cell) to drive the tri-state buffers (buf), subsequently reducing the maximum frequency of the memory cells (cell).

The write controlling switches (SW) are then used to “fragment” the write bit line (WBL). As a result, the parasitic capacitance attributed to the write bit line (WBL) can be reduced compared to the conventional configuration.

Additionally, using the configuration of the second preferred embodiment, when the to-be-read data is an inverted form of the preset bias voltage, the undesired situation that electrical current flows across the resistors (R) due to the large voltage across the resistors (R) may be prevented, reducing unnecessary power dissipation attributed thereto.

The second preferred embodiment has the same advantages as those of the first preferred embodiment.

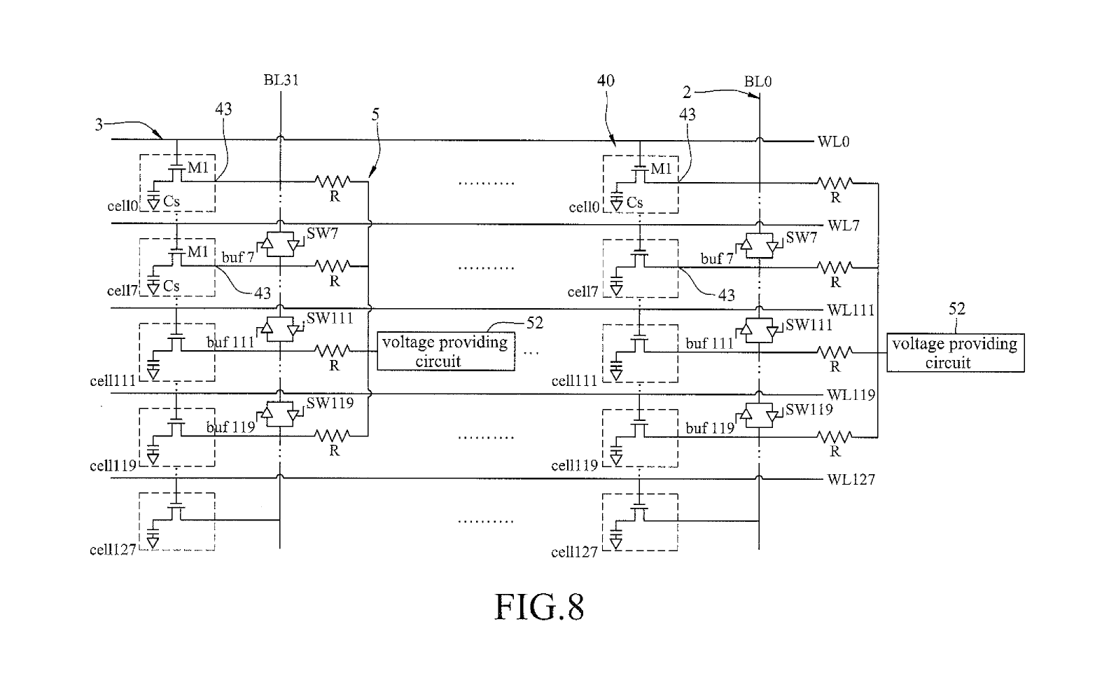

As shown in FIG. 8, the third preferred embodiment of the semiconductor memory device according to the present invention is illustrated. The semiconductor memory device includes a memory cell array, a data line unit (BL), a control unit (WL), a buffer unit and a bias voltage unit 5.

The memory cell array includes a plurality of memory cell groups 40, each of the memory cell groups 40 including a plurality of memory cells (cell).

The data line unit (BL) is coupled to the memory cell groups 40, and includes a plurality of data lines spaced apart and electrically isolated from each other. Specifically, the data line unit (BL) is configured to receive to-be-read data from the memory cell groups 40 during a read period of an operation cycle, and is configured to transmit to-be-written data to the memory cell groups 40 during a write period of the operation cycle.

The control line unit (WL) is coupled to the memory cell groups 40, and includes a plurality of control lines spaced apart and electrically isolated from each other for transmitting a control signal to the memory cell groups 40.

The buffer unit includes a plurality of tri-state buffer sets and a write controlling switch component unit.

Each of the tri-state buffer sets includes a string of tri-state buffers (buf)) that are disposed on a signal transmission path of a respective one of the data lines. Each of the tri-state buffers has an input terminal coupled to a respective one of the memory cells (cell) to receive data therefrom, and an output terminal coupled to the input terminal of a succeeding one of the tri-state buffers (buf)) in the string. The tri-state buffers (buf) are controlled to switch between a conducting state and a non-conducting state.

The write controlling component unit includes a plurality of write controlling switches (SW) each coupled in parallel with a respective one of the tri-state buffers (buf). The write controlling switches (SW) are controlled to switch between a conducting state and a non-conducting state.

The bias voltage unit 5 is coupled to the data lines and is operable to supply a preset bias voltage thereto. Specifically, the bias voltage unit 5 includes a plurality of voltage providing circuits 52 and a plurality of resistors (R). Each of the voltage providing circuits 52 is for providing the preset bias voltage to a respective one of the data lines (BL). Each of the resistors (R) has one end coupled to a respective one of the data lines (BL), and another end coupled to the corresponding one of the voltage providing circuits 52.

Since operations of this embodiment are similar to those of the second embodiment, details thereof are omitted herein for the sake of brevity.

One advantage of this embodiment is that the number of voltage providing circuits 52 used for the entire semiconductor memory device is much less compared to that in the embodiment shown in FIG. 6, thereby reducing the overall size and cost of the semiconductor memory device. It is apparent that in some variations, other number of voltage providing circuits 52 may be employed. For example, the bias voltage unit 5 may include only a single voltage providing circuit 52.

The third preferred embodiment has the same advantages as those of the first preferred embodiment.

To sum up, embodiments of the present invention eliminate the need to incorporate a sense amplifier into the semiconductor memory device, thus reducing the power consumption thereof. In addition, the maximum frequency under which the semiconductor memory device can operate may be increased.

In this disclosure, the term “coupled to” should not be restricted to a mechanical or physical coupling based on an inference from the written description, but could include electrical coupling.

While the present invention has been described in connection with what are considered the most practical and preferred embodiments, it is understood that this invention is not limited to the disclosed embodiments but is intended to cover various arrangements included within the spirit and scope of the broadest interpretation so as to encompass all such modifications and equivalent arrangements.

What is claimed is:

1. A semiconductor memory device comprising:
a memory cell array including a plurality of memory cell groups, each of said memory cell groups including a plurality of memory cells, each of said memory cells having a read terminal and a write terminal;
a data line unit that is coupled to said memory cell groups and that includes a plurality of read bit lines and a plurality of write bit lines that are spaced apart and electrically isolated from each other, each of said read bit lines being coupled to said read terminals of said memory cells of a respective one of said memory cell groups for transmitting to-be-read data, each of said write bit lines being coupled to said write terminals of said memory cells of a respective one of said memory cell groups for transmitting to-be-written data;
a control unit that is coupled to said memory cell groups, that is electrically isolated from said data line unit, and that includes a plurality of read word lines and a plurality of write word lines that are spaced apart and electrically isolated from each other, said read word lines being configured to transmit a read control signal to said memory cell groups, said write word lines being configured to transmit a write control signal to said memory cell groups;
a buffer unit including a plurality of tri-state buffer sets, each of said tri-state buffer sets including a string of tri-state buffers that are coupled in series with a respective one of said read bit lines, each of said tri-state buffers having an input terminal coupled to said read terminal of a respective one of said memory cells to receive the to-be-read data, and an output terminal coupled to said input terminal of a succeeding one of said tri-state buffers in the string, said tri-state buffers being controlled to switch between a conducting state and a non-conducting state; and
a bias voltage unit coupled to said read bit lines and operable to supply a preset bias voltage thereto.

2. The semiconductor memory device of claim 1, wherein:
said bias voltage unit is operable to switch between a biasing mode, in which the preset bias voltage is supplied to said read bit lines, and a non-biasing mode, in which the preset bias voltage is not supplied to said read bit lines; and
said bias voltage unit is switched to the non-biasing mode when data is to be read from said memory cell groups.

3. The semiconductor memory device of claim 2, wherein said bias voltage unit includes a voltage providing circuit coupled to a common node of every adjacent pair of said tri-state buffers on said read bit lines for supplying the preset bias voltage thereto when said bias voltage unit is operated in the biasing mode.

4. The semiconductor memory device of claim 3, wherein each of said memory cells includes:
a first transistor having a first terminal, a second terminal coupled to said write terminal, and a control terminal coupled to one of said write word lines;
a second transistor having a first terminal, a second terminal disposed to receive a reference voltage, and a control terminal coupled to said first terminal of said first transistor;
a capacitor having one end coupled to said control terminal of said second transistor, and another end disposed to receive the reference voltage; and
a third transistor having a first terminal coupled to said read terminal, a second terminal coupled to said first terminal of said second transistor, and a control terminal coupled to one of said read word lines.

5. The semiconductor memory device of claim 2, wherein said bias voltage unit includes at least one switch for coupling a common node of every adjacent pair of said tri-state buffers on said read bit lines to the preset bias voltage, said at least one switch being closed when said bias voltage unit is operated in the biasing mode, and being open when said bias voltage unit is operated in the non-biasing mode.

6. The semiconductor memory device of claim 1, wherein each of said tri-state buffers includes a switch component and a buffer component coupled in series.

7. A semiconductor memory device comprising:
a memory cell array including a plurality of memory cell groups, each of said memory cell groups including a plurality of memory cells, each of said memory cells including a data terminal;
a first data line unit that includes a plurality of first data lines spaced apart and electrically isolated from each other, each of said first data lines being coupled to said data terminals of said memory cells of a respective one of said memory cell groups;
a control unit that is coupled to said memory cell groups, and that includes a plurality of control lines spaced apart and electrically isolated from each other for transmitting a control signal to said memory cell groups;
a buffer unit including a plurality of tri-state buffer sets, each of said tri-state buffer sets including a string of tri-state buffers that are coupled in series with a respective one of said first data lines, each of said tri-state buffers having an input terminal coupled to said data terminal of a respective one of said memory cells to receive data therefrom, and an output terminal coupled to said input terminal of a succeeding one of said tri-state buffers in the string, said tri-state buffers being controlled to switch between a conducting state and a non-conducting state; and
a bias voltage unit coupled to said first data lines and operable to supply a preset bias voltage thereto.

8. The semiconductor memory device of claim 7, wherein said first data lines are read bit lines for transmitting to-be-read data, said semiconductor memory device further comprising:
a second data line unit including a plurality of second data lines that are spaced apart and electrically isolated from each other, each of said second data lines being a write bit line coupled to said data terminals of said memory cells of a respective one of said memory cell groups for transmitting to-be-written data; and
a write controlling component unit including a plurality of write controlling component sets, each of said write controlling component sets including a string of write controlling switches that are coupled in series with a respective one of second data lines, each of said write controlling switches having an input terminal coupled to said data terminal of a respective one of said memory cells, and an output terminal coupled to said input terminal of a succeeding one of said write controlling switches in the string, said write controlling switches being controlled to switch between a conducting state and a non-conducting state.

9. The semiconductor memory device of claim 8, wherein said bias voltage unit is further coupled to said second data lines for supplying the preset bias voltage thereto, and is operable to switch between a biasing mode, in which the preset bias voltage is supplied to said first data lines and said second data lines, and a non-biasing mode, in which the preset bias voltage is not supplied to said first data lines and said second data lines; and
said bias voltage unit is switched to the non-biasing mode when data is to be read from said memory cell groups.

10. The semiconductor memory device of claim 9, wherein said bias voltage unit includes a voltage providing circuit coupled to a common node of every adjacent pair of said tri-state buffers and a common node of every adjacent pair of said write controlling switches for supplying the preset bias voltage thereto when said bias voltage unit is operated in the biasing mode.

11. The semiconductor memory device of claim 9, wherein said bias voltage unit includes at least one switch for coupling a common node of every adjacent pair of said tri-state buffers and a common node of every adjacent pair of said write controlling switches to the preset bias voltage;
said at least one switch being closed when said bias voltage unit is operated in the biasing mode, and being opened when said bias voltage unit is operated in the non-biasing mode.

12. The semiconductor memory device of claim 7, wherein:
said first data line unit is configured to receive to-be-read data from said memory cell groups during a read period of an operation cycle, and is configured to transmit to-be-written data to said memory cell groups during a write period of the operation cycle;
said input terminals of said tri-state buffers are disposed to receive the to-be-read data; and
said semiconductor memory device further comprises a write controlling component unit that includes a plurality of write controlling switches each coupled in parallel with a respective one of said tri-state buffers, said write controlling switches being controlled to switch between a conducting state and a non-conducting state.

13. The semiconductor memory device of claim 12, wherein said bias voltage unit is operable to switch between a biasing mode, in which the preset bias voltage is supplied to said first data lines, and a non-biasing mode, in which the preset bias voltage is not supplied to said first data lines; and
said bias voltage unit is switched to the non-biasing mode when data is to be read from said memory cell groups.

14. The semiconductor memory device of claim 13, wherein said bias voltage unit includes a voltage providing circuit coupled to a common node of every adjacent pair of said tri-state buffers for supplying the preset bias voltage thereto when said bias voltage unit is operated in the biasing mode.

15. The semiconductor memory device of claim 13, wherein said bias voltage unit includes at least one switch for coupling a common node of every adjacent pair of said tri-state buffers to the preset bias voltage, said at least one switch being closed when said bias voltage unit is operated in the biasing mode, and being opened when said bias voltage unit is operated in the non-biasing mode.

16. The semiconductor memory device of claim 7, wherein each of said tri-state buffers includes a switch component and a buffer component coupled in series.

17. The semiconductor memory device of claim 7, wherein said write controlling switches are implemented using tri-state buffers.

18. A semiconductor memory device comprising:
a memory cell array including a plurality of memory cell groups, each of said memory cell groups including a plurality of memory cells;
a data line unit that is coupled to said memory cell groups, and that includes a plurality of data lines spaced apart and electrically isolated from each other;
a control unit that is coupled to said memory cell groups, and that includes a plurality of control lines spaced apart and electrically isolated from each other for transmitting a control signal to said memory cell groups;
a buffer unit including a plurality of tri-state buffer sets, each of said tri-state buffer sets including a string of tri-state buffers that are disposed on a signal transmission path of a respective one of said data lines, each of said tri-state buffers having an input terminal coupled to a respective one of said memory cells to receive data therefrom, and an output terminal coupled to said input terminal of a succeeding one of said tri-state buffers in the string, said tri-state buffers being controlled to switch between a conducting state and a non-conducting state; and
a bias voltage unit coupled to said data lines and operable to supply a preset bias voltage thereto.

19. The semiconductor memory device of claim 18, wherein each of said tri-state buffers includes a switch component and a buffer component coupled in series.
